(19) United States
(12) Patent Application Publication
(10) Pub. No.: US 2013/0011282 A1
(43) Pub. Date: Jan. 10, 2013

(54) PIEZOELECTRIC ELEMENT DRIVE CIRCUIT AND LIQUID EJECTING APPARATUS

(75) Inventor: Atsushi OSHIMA, Shiojiri-shi (JP)

(73) Assignee: SEIKO EPSON CORPORATION, Tokyo (JP)

(21) Appl. No.: 13/541,335

(22) Filed: Jul. 3, 2012

(30) Foreign Application Priority Data
Jul. 5, 2011 (JP) 2011-148900

(51) Int. Cl. F04B 45/047; H01L 41/09

(52) U.S. Cl. 417/413.2; 310/317

(57) ABSTRACT

A drive waveform signal as a reference of a drive signal to be applied to a piezoelectric element is power-amplified, and the drive signal after passing through a coil is applied to the piezoelectric element. A resonant circuit is formed of the coil and the piezoelectric element, and a resonant peak is suppressed by performing a phase advance compensation of the drive signal and by performing a negative feedback. At this time, the degree of suppression of the peak is adjusted so that a slight reverse voltage is generated. Since this can eliminate residual distortion of the piezoelectric element by the reverse voltage, even when driving is performed at a high repetition frequency, the original amount of deformation can be ensured. Besides, the circuit does not become complicated.

### BACKGROUND

1. Technical Field

The present invention relates to a technique to drive a piezoelectric element.

2. Related Art

A piezoelectric element typified by PZT (lead zirconate titanate) has such a characteristic (so-called piezoelectric characteristic) that expansion occurs when a positive voltage is applied and contraction occurs when the positive voltage is removed. If this characteristic is used, an actuator can be constructed which responds at a high respond speed by application of a drive voltage, and is small and generates a large force. Thus, for example, the piezoelectric element is mounted as an actuator in a liquid ejecting apparatus typified by an inkjet printer, and is industrially widely used.

Besides, the piezoelectric element has such a property that for example, after the expansion is caused by the application of the positive voltage, when the piezoelectric element is contracted by removing the voltage, residual distortion is generated. Although the residual distortion is eliminated when the piezoelectric element is left for a while in a state where the voltage is removed, if the positive voltage is again applied in the state where the residual distortion remains, the expansion amount of the piezoelectric element is reduced by the amount of the residual distortion. Thus, the original performance of the piezoelectric element can not be sufficiently exhibited. The same applies to a case where a negative voltage is applied and the piezoelectric element is contracted.

Then, a technique is proposed in which the positive voltage applied to the piezoelectric element is removed, and further, the negative voltage is successively applied to quickly eliminate the residual distortion, and consequently, even when the voltage is applied at a high repetition frequency, the original amount of deformation of the piezoelectric element can be ensured (JP-A-2006-121928).

However, in the related art, since a power supply to generate a low voltage for eliminating the residual distortion is additionally required in addition to a power supply to generate the voltage for deforming the piezoelectric element, there is a problem that a drive circuit of the piezoelectric element becomes large.

### SUMMARY

An advantage of some aspects of the invention is to provide a technique in which even when a piezoelectric element is driven at a high repetition frequency, the original amount of deformation of the piezoelectric element is ensured, and an increase in size of a drive circuit of the piezoelectric element can be avoided.

An aspect of the invention is directed to a piezoelectric element drive circuit for driving a piezoelectric element by applying a specified drive signal to the piezoelectric element including a drive waveform signal output circuit to output a drive waveform signal as a reference of the drive signal, an arithmetic circuit to generate an error signal by taking a difference between the drive waveform signal and a feedback signal generated using the drive signal applied to the piezoelectric element, a power amplifier that receives power from a power supply and power-amplifies the error signal to generate a power amplified signal whose voltage changes between a power supply voltage generated by the power supply and a ground voltage of the power supply, an inductive element that connects the power amplifier to the piezoelectric element and supplies the power amplified signal from the power amplifier as the drive signal to the piezoelectric element, and a compensator that feeds back negatively a signal, which is obtained by performing a phase advance compensation, as a compensation to advance a phase, of the drive signal from the inductive element, as the feedback signal to the arithmetic circuit. The compensator is a circuit in which a lowest voltage of the drive signal applied to the piezoelectric element becomes lower than the ground voltage of the power supply.

In the piezoelectric element drive circuit having the structure as stated above, the drive signal is applied to the piezoelectric element in a manner as described below. First, the error signal is generated by taking the difference between the drive waveform signal as the reference of the drive signal and the feedback signal generated from the drive signal actually applied to the piezoelectric element. Next, the error signal is power-amplified to generate the power-amplified signal whose voltage changes between the power supply voltage and the ground voltage of the power supply. Then, the power-amplified signal is supplied to the piezoelectric element through the inductive element, so that the drive signal is applied to the piezoelectric element. When the inductive element is combined with the piezoelectric element, a resonant circuit is formed. Then, after the compensation (phase advance compensation) is performed to advance the phase of the drive signal applied to the inductive element, the obtained signal is negatively fed back as the feedback signal to the arithmetic circuit, so that a resonant characteristic between the inductive element and the piezoelectric element is suppressed. However, the resonant characteristic is not completely suppressed, but the resonant characteristic is suppressed by adjusting a characteristic of the compensator (for example, when the compensator is constructed of an RC differential circuit, at least one of a resistance value of the circuit and a capacitance of a capacitor is adjusted), so that the lowest voltage of the drive signal applied to the piezoelectric element becomes a voltage lower than a voltage (ground voltage of the power supply) in an initial state.

By doing so, even if a power supply to generate the voltage lower than the voltage (ground voltage of the power supply) in the initial state of the drive signal is not used, the lowest voltage of the drive signal can be made the voltage lower than the voltage in the initial state, and the residual distortion generated in the piezoelectric element can be made small. Thus, the size of the drive circuit is not increased. Since the residual distortion generated in the piezoelectric element can be made small, even when the piezoelectric element is driven at the high repetition frequency, the piezoelectric element can be driven without receiving much influence of the residual distortion. Besides, the efficiency of driving the piezoelectric element can be improved by the reduction of the residual distortion.

In the piezoelectric element drive circuit, a characteristic of a phase advance compensation circuit is adjusted such that a voltage difference between the lowest voltage of the drive signal applied to the piezoelectric element and the ground voltage is a value of ten to twenty percent of a voltage difference between a highest voltage (voltage at which the deformation amount of the piezoelectric element becomes largest) of the drive signal and the ground voltage.

As a result of experiments performed under various conditions, it is found that the magnitude of the residual distortion generated after the deformation of the piezoelectric element is ten to twenty percent of the deformation amount at the time when the largest deformation occurs. Since a maximum value of the deformation amount is determined by the voltage difference between the voltage (ground voltage of the power supply) in the initial state of the drive signal applied to the piezoelectric element and the highest voltage of the drive signal, if the voltage is made lower than the voltage in the initial state by ten to twenty percent of the voltage difference, the residual distortion of the piezoelectric element can be almost eliminated. From this, if the characteristic of the compensator is adjusted so that the voltage difference between the lowest voltage of the drive signal and the ground signal is the value of ten to twenty percent of the voltage difference between the highest voltage of the drive signal and the ground voltage, the residual distortion generated in the piezoelectric element can be almost eliminated. Accordingly, the original amount of deformation of the piezoelectric element can be ensured.

The piezoelectric element drive circuit may further include a capacitive element connected in parallel to the piezoelectric element.

As stated above, in the piezoelectric element drive circuit, a resonant phenomenon occurring between the inductive element and the piezoelectric element is used, so that the lowest voltage of the drive signal applied to the piezoelectric element is made the voltage lower than the voltage (ground voltage of the power supply) in the initial state. Accordingly, such an effect is obtained in a frequency range close to a resonant frequency of the resonant circuit. Here, although the resonant frequency is determined by an inductance of the inductive element and a capacitance of the piezoelectric element, the capacitance of the piezoelectric element is determined to a certain degree by the size, characteristics and the like of the piezoelectric element. Accordingly, the inductance of the inductive element must be adjusted in order to obtain a desired resonant frequency, and a case can occur in which a large inductive element is required. In such a case, if the capacitive element (capacitor etc.) is connected in parallel to the piezoelectric element, even if the capacitance of the piezoelectric element is not changed, a capacitive load having a combined capacitance of the piezoelectric element and the capacitive element can be regarded as being connected to the inductive element. Thus, it is not indispensable to mount the large inductive element, and the piezoelectric element drive circuit can be miniaturized.

The piezoelectric element drive circuit may include the following power amplifier. That is, the power amplifier includes a modulator to generate a modulated signal by pulse-modulating the error signal obtained by the arithmetic circuit, and a digital power amplifier that receives the power from the power supply and generates the power-amplified signal by digitally power-amplifying the modulated signal.

In the piezoelectric element drive circuit including the power amplifier as stated above, the modulated signal is generated by pulse-modulating the error signal, and the obtained modulated signal is power-amplified to generate a pulse wave-shaped power-amplified signal whose voltage value is changed between the power supply voltage and the ground voltage of the power supply. Here, the digital power amplifier switches ON/OFF of two switch elements push-pull connected to the power supply and having a low ON resistance and performs digital power amplifying while the pulse wave shape is maintained. Thus, as compared with a case where analog power amplification of the error signal is performed while an analog waveform is maintained, power loss can be greatly suppressed. Besides, as described above, the piezoelectric element drive circuit uses the resonant phenomenon occurring between the inductive element and the piezoelectric element, and a low pass filter having an attenuation characteristic is constructed in a frequency area of the resonant frequency or higher. That is, a modulation frequency in the modulator is set to be sufficiently higher than the resonant frequency (or cutoff frequency), so that a modulation component of the power-amplified signal is removed, and a power-amplified signal component (signal component of the drive waveform signal) can be applied as the drive signal to the piezoelectric element.

Besides, as described above, even when the piezoelectric element is driven at the high repetition frequency, the piezoelectric element drive circuit hardly receives the influence of the residual distortion and can drive the piezoelectric element, and the circuit can be miniaturized. Accordingly, the piezoelectric element drive circuit can be suitably applied to a liquid ejecting apparatus to eject liquid by driving the piezoelectric element, and the invention can be implemented as a liquid ejecting apparatus.

That is, another aspect of the invention is directed to a liquid ejecting apparatus including a pulsation generating part including a liquid chamber into which liquid flows, a piezoelectric element to deform the liquid chamber, and an ejection nozzle to eject the liquid flowing into the liquid chamber. The drive signal outputted from the foregoing piezoelectric element drive circuit is applied to the piezoelectric element, and the liquid flowing into the liquid chamber is ejected from the ejection nozzle.

In the liquid ejecting apparatus as stated above, even when the piezoelectric element is driven at the high repetition frequency, the deformation amount of the piezoelectric element can be sufficiently ensured without receiving the influence of the residual distortion. Thus, the liquid ejecting apparatus can be provided in which even when the liquid is ejected at the high repetition frequency from the ejection nozzle, the ejection amount is stable.

### BRIEF DESCRIPTION OF THE DRAWINGS

The invention will be described with reference to the accompanying drawings, wherein like numbers reference like elements.

FIG. 1 is an explanatory view exemplifying a liquid ejecting apparatus including a piezoelectric element drive circuit of an embodiment.

FIG. 2 is an explanatory view showing a circuit structure of the piezoelectric element drive circuit of the embodiment.

FIG. 3 is an explanatory view showing a state where substantial electrostriction of a piezoelectric element is reduced due to residual distortion of the piezoelectric element.

FIGS. 4A and 4B are explanatory views in which the residual distortion generated in the piezoelectric element is shown on a plane specified by an applied voltage and electrostriction of the piezoelectric element.

FIG. 5A is a block diagram for analysis of frequency response characteristics of the piezoelectric element drive circuit of the embodiment, and FIGS. 5B to 5D show transfer functions.

FIGS. 6A and 6B are board diagrams showing the frequency response characteristics of the piezoelectric element drive circuit of the embodiment.

FIGS. 7A to 7D are explanatory views exemplifying the operation of the piezoelectric element drive circuit of the embodiment.

FIG. 8 is an explanatory view exemplifying a case where the piezoelectric element is driven by using the piezoelectric element drive circuit of the embodiment.

FIG. 9 is an explanatory view in which the behavior of the piezoelectric element driven by using the piezoelectric element drive circuit of the embodiment is shown on the plane specified by the applied voltage and the electrostriction of the piezoelectric element.

FIG. 10 is an explanatory view showing a part of a piezoelectric element drive circuit of a modified example.

### DESCRIPTION OF EXEMPLARY EMBODIMENTS

Hereinafter, embodiments will be described in the following order in order to clarify the contents of the invention.

A. Apparatus Structure

B. Circuit Structure of Piezoelectric Element Drive Circuit

C. Operation of Piezoelectric Element Drive Circuit

D. Modified Example

### A. Apparatus Structure:

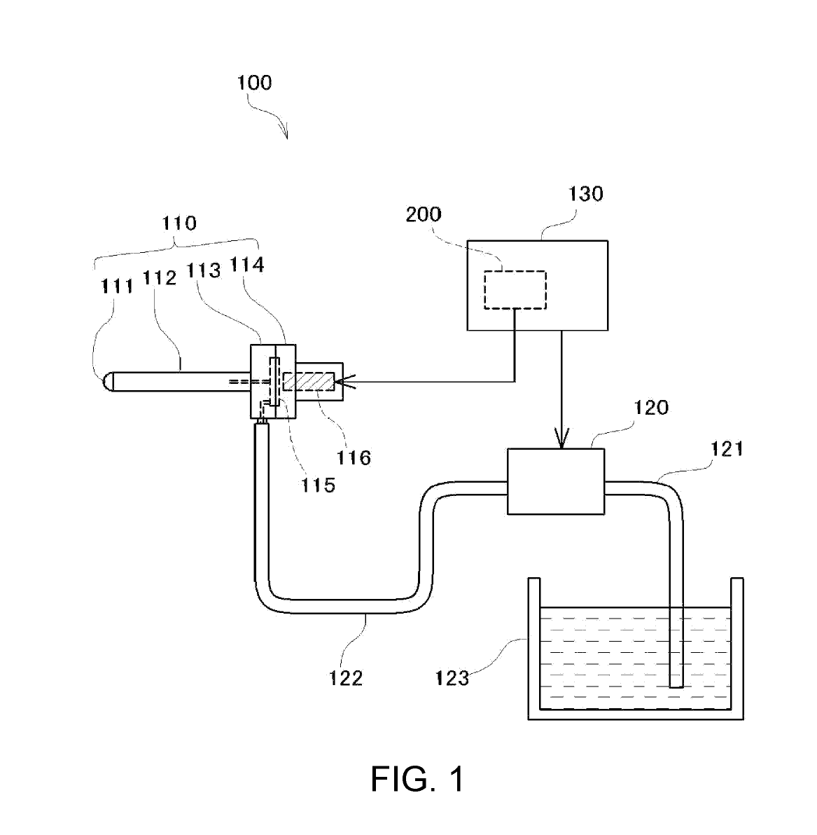

FIG. 1 is an explanatory view showing a structure of a liquid ejecting apparatus 100 including a piezoelectric element drive circuit 200 of an embodiment. As shown in the drawing, the liquid ejecting apparatus 100 roughly includes an ejection unit 110 to eject liquid, a liquid supply unit 120 to supply the liquid to be ejected from the ejection unit 110 to the ejection unit 110, and a control unit 130 to control the operation of the ejection unit 110 and the liquid supply unit 120.

The ejection unit 110 has a structure in which a metal first case 114 and a metal second case 113 are stacked on each other. A cylindrical liquid ejection pipe 112 is standingly provided on a front surface of the second case 113, and a nozzle 111 is attached to a tip of the liquid ejection pipe 112. A disk-shaped liquid chamber 115 is formed on a mating surface between the second case 113 and the first case 114, and the liquid chamber 115 is connected to the nozzle 111 through the liquid ejection pipe 112. A laminated piezoelectric element 116 is provided inside the first case 114. The liquid supply unit 120 sucks the liquid through a first connection tube 121 from a liquid container 123 in which the liquid (water, normal saline solution, drug solution, etc.) to be ejected is stored, and then supplies the liquid into the liquid chamber 115 of the ejection unit 110 through a second connection tube 122. Therefore, the liquid chamber 115 is filled with the liquid.

When the control unit 130 applies a drive signal to the piezoelectric element 116, the piezoelectric element 116 expands and the liquid chamber 115 is compressed, and consequently, the liquid in the liquid chamber 115 is ejected in a pulse form from the nozzle 111. When the application of the drive signal is stopped (when a voltage of the drive signal is returned to a voltage in an initial state), the piezoelectric element 116 is contracted, and the compressed liquid chamber 115 returns to an original state. However, the piezoelectric element 116 is not immediately contracted to the original state when the application of the drive signal is stopped. Although the details will be described later, a slight (about ten to twenty percent of the amount of expansion) residual distortion is generated in the piezoelectric element 116 for a short period after the application of the drive signal is stopped. When the drive signal is applied in the state where the residual distortion is generated, since the amount of expansion of the piezoelectric element 116 is reduced by the amount of the residual distortion, the amount of liquid ejected from the nozzle 111 is reduced. If a further lower voltage is applied after the application of the drive signal is stopped, the residual distortion of the piezoelectric element 116 can be eliminated. However, if another power supply is used for that purpose, the control unit 130 becomes large. Then, in order to eliminate the residual distortion of the piezoelectric element 116 without using another power supply, the control unit 130 of the embodiment includes the piezoelectric element drive circuit 200 as described below.

### B. Circuit Structure of Piezoelectric Element Drive Circuit

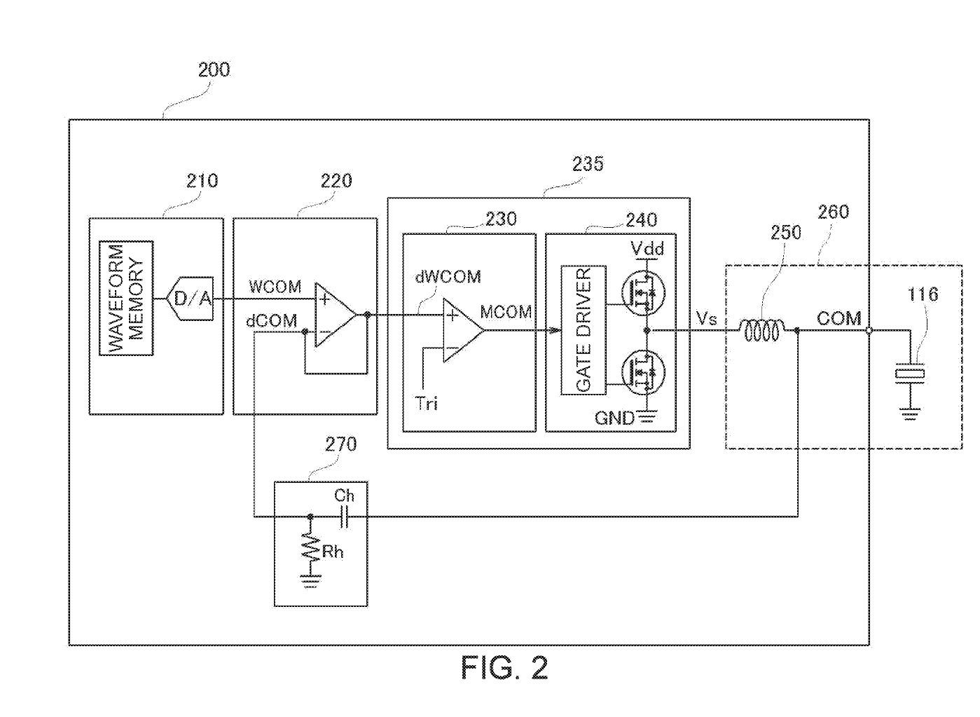

FIG. 2 is an explanatory view showing a circuit structure of the piezoelectric element drive circuit 200 of the embodiment. As shown in the drawing, the piezoelectric element drive circuit 200 roughly includes a drive waveform signal generator (drive waveform signal output circuit) 210 to output a drive waveform signal (hereinafter referred to as WCOM) as a reference of the drive signal, an arithmetic circuit 220 to output an error signal (hereinafter referred to as dWCOM) based on WCOM received from the drive waveform signal generator 210 and an after-mentioned feedback signal (hereinafter referred to as dCOM), a power amplifier 235 to generate a power amplified signal (hereinafter referred to as Vs) by power-amplifying dWCOM from the arithmetic circuit 220, a coil 250 (inductive element) that receives Vs from the power amplifier 235 and supplies it as the drive signal (hereinafter referred to as COM) to the piezoelectric element 116 of the ejection unit 110, and a compensator 270 to generate dCOM (feedback signal) by performing phase advance compensation of COM supplied from the coil 250 to the piezoelectric element 116. Here, the power amplifier 235 includes a modulator 230 to convert dWCOM from the arithmetic circuit 220 into a modulated signal (hereinafter referred to as MCOM) by pulse modulation, and a digital power amplifier 240 to generate the power amplified signal (Vs) by power-amplify MCOM from the modulator 230.

The drive waveform signal generator 210 includes a waveform memory to store data of WCOM and a D/A converter, and generates WCOM (drive waveform signal) by converting the data read from the waveform memory into an analog signal by the D/A converter. The generated WCOM is inputted to a non-inverted terminal of the arithmetic circuit 220. Besides, dCOM (feedback signal) from the compensator 270 is inputted to an inverted input terminal of the arithmetic circuit 220. As a result, a signal corresponding to a difference between WCOM and dCOM is outputted as dWCOM (error signal) from the arithmetic circuit 220.

Subsequently, the modulator 230 compares dWCOM with a triangular wave (hereinafter referred to as Tri) having a specific period, and generates such a pulse wave-shaped MCOM (modulated signal) that a high voltage state occurs if dWCOM is larger, and a low voltage state occurs if dWCOM is smaller. The obtained MCOM is inputted to the digital power amplifier 240. The digital power amplifier 240 includes a power supply, two switch elements (MOSFET etc.) push-pull connected to the power supply, and a gate driver to drive the switch elements. When MCOM is in the high voltage state, the switch element on the power supply side (high side) is turned ON, the switch element on the low side is turned OFF, and a voltage (power supply voltage Vdd) generated by the power supply is outputted as Vs. When MCOM is in the low voltage state, the switch element on the high side is turned OFF, the switch element on the low side is turned ON, and a ground voltage GND of the power supply is outputted as Vs. Accordingly, MCOM changing in the pulse wave form can be power-amplified to Vs changing in the pulse wave form between the power supply voltage Vdd and the ground voltage GND.

In this power amplification, ON/OFF of the two switch elements push-pull connected to the power supply are switched, and a current flows through the switch element in the ON state. However, since an ON resistance of the switch element (MOSFET etc.) is very low, loss in the switch hardly occurs. Thus, as compared with a case where the error signal is power-amplified in an analog waveform, the power loss can be greatly suppressed. As a result, power saving by improvement of power efficiency becomes possible, and further, a large heat sink for heat dissipation is not required to be provided, and the circuit can be miniaturized.

The thus power-amplified Vs (power amplified signal) passes through the coil 250 and then is applied as COM (drive signal) to the piezoelectric element 116. Although the details will be described later, the coil 250 is combined with a capacitance of the piezoelectric element 116, and constitutes a low pass filter 260. A modulated frequency of the modulator 230 is set to be higher than a cutoff frequency of the low pass filter 260, so that a modulated component in Vs is attenuated by the low pass filter 260, and a signal component in Vs is extracted and is demodulated as COM.

Since COM applied to the piezoelectric element 116 is negatively fed back, the piezoelectric element drive circuit 200 is a feedback control system. However, a phase of COM passing through the coil 250 is delayed from that of WCOM by a phase characteristic of the low pass filter 260. Then, COM is not simply negatively fed back, but is compensated to advance the phase through the compensator 270 including a capacitor Ch and a resistor Rh, and the obtained signal is inputted as dCOM to the inverted input terminal of the arithmetic circuit 220, so that the negative feedback is performed.

### C. Operation of Piezoelectric Element Drive Circuit

The piezoelectric element drive circuit 200 of the embodiment having the structure as stated above has such an excellent characteristic that the residual distortion generated in the piezoelectric element 116 can be quickly eliminated although another power supply to eliminate the residual distortion is not provided (the details will be described later). As a result, the piezoelectric element 116 can be driven at a high repetition frequency (that is, at a short interval) without increasing the size of the circuit or complicating the circuit. Hereinafter, the reason why the excellent characteristic is obtained will be described. As preparation for that, a phenomenon in which a substantial amount of deformation of the piezoelectric element 116 is reduced by the residual distortion generated in the piezoelectric element 116 will be described in brief.

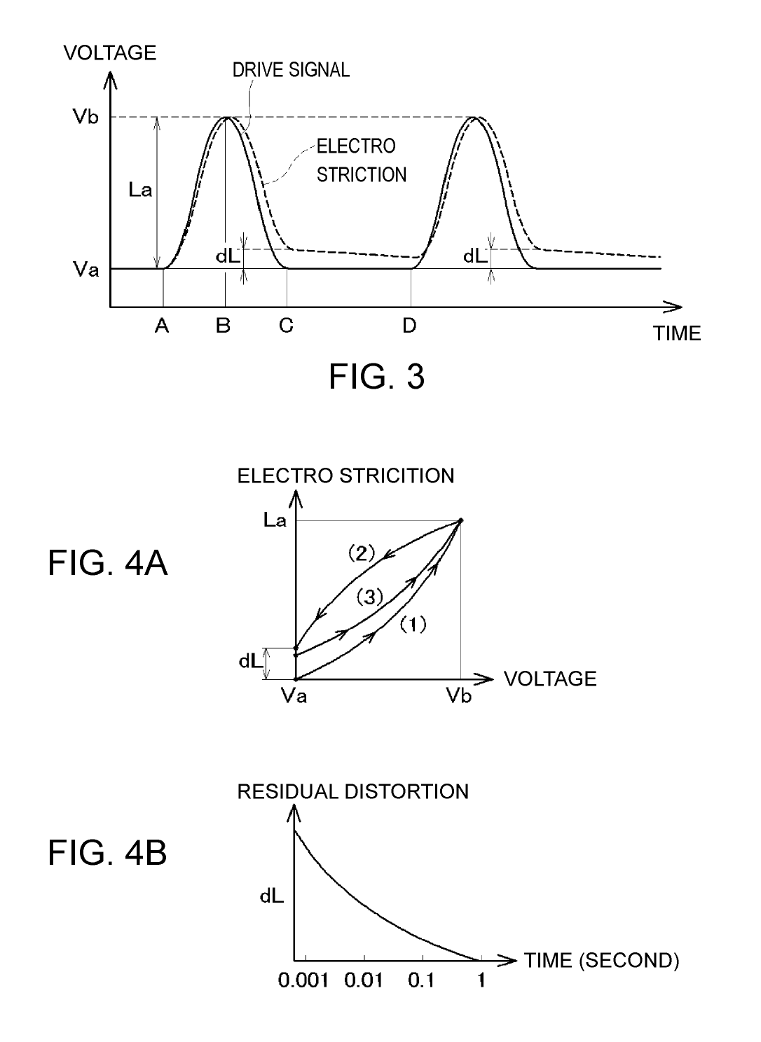

FIG. 3 is an explanatory view showing the electrostriction of the piezoelectric element 116 when a drive signal having a certain waveform is repeatedly applied to the piezoelectric element 116. A waveform indicated by a solid line in the drawing represents the drive signal, and a waveform indicated by a broken line represents the electrostriction of the piezoelectric element 116 generated by the application of the drive signal. Incidentally, the electrostriction of the piezoelectric element 116 means the amount of deformation of the piezoelectric element 116 with reference to the length before (initial state) the drive signal is applied. The horizontal axis represents the passage of time.

When a voltage of the drive signal is increased from a voltage Va in the initial state to a voltage Vb during a period from a time point A to a time point B shown in the drawing, the piezoelectric element 116 is deformed (expanded) and the electrostriction becomes La. Thereafter, even if the voltage of the drive signal is returned from the voltage Vb to the voltage Va during a period from the time point B to a time point C in the drawing, the electrostriction of the piezoelectric element 116 is not completely returned to the original state, and a residual distortion dL is generated. The residual distortion is reduced with the lapse of time as indicated by the broken line in FIG. 3. However, when the voltage of the drive signal is increased from the voltage Va to the voltage Vb at a time point D when the residual distortion is not completely eliminated, the electrostriction of the piezoelectric element 116 at the time point when the voltage reaches the voltage Vb becomes La. That is, the amount of electrostriction from the time point D becomes small by the amount of the residual distortion. In other words, when the piezoelectric element 116 is driven under a condition where the residual distortion remains (for example, a condition that driving is performed at the high repetition frequency), the electrostriction is reduced by the amount of the residual distortion from the amount of electrostriction which should have been originally obtained according to the amount of change of the applied voltage.

FIGS. 4A and 4B are explanatory views in which a state where the residual distortion is generated in the piezoelectric element 116 is shown on a plane specified by the voltage applied to the piezoelectric element 116 and the electrostriction of the piezoelectric element 116. As shown in FIG. 4A, when the voltage applied to the piezoelectric element 116 is increased from the voltage Va in the initial state to the voltage Vb, the electrostriction of the piezoelectric element 116 increases to La through a path (1) shown in the drawing. Subsequently, when the voltage applied to the piezoelectric element 116 is reduced, the electrostriction of the piezoelectric element 116 is reduced through a path (2) in the drawing. However, even if the voltage is returned to the voltage Va in the initial state, the residual distortion of dL remains. If the voltage Va in the initial state is kept, the residual distortion dL is reduced with the lapse of time. However, when the voltage is again increased to the voltage Vb while the residual distortion remains, the electrostriction of the piezoelectric element 116 increases to La through a path (3) shown in FIG. 4A. As stated above, when the drive signal is repeatedly applied to the piezoelectric element 116, the electrostriction of the piezoelectric element 116 increases through the path (3) and decreases through the path (2). Thus, the substantial amount of electrostriction of the piezoelectric element 116 is reduced by the amount of the residual distortion. As a result, in the liquid ejecting apparatus 100 shown in FIG. 1, the amount of ejection of the liquid is decreased.

Of course, after the voltage of the piezoelectric element 116 is returned to the voltage Va in the initial state, if the voltage Va is kept until the residual distortion is eliminated, the decrease of the substantial amount of electrostriction of the piezoelectric element 116 can be avoided. However, as shown in FIG. 4B, since a time of about one second is required before the residual distortion dL is almost eliminated, the piezoelectric element 116 can not be driven at the high repetition frequency. In order to avoid this, the residual distortion of the piezoelectric element 116 is required to be cancelled by the application of a voltage lower than the voltage Va in the initial state. For that purpose, an additional power supply is required, and there is a problem that the drive circuit becomes large and is complicated.

On the other hand, in the piezoelectric element drive circuit 200 of the embodiment having the structure shown in FIG. 2, although the circuit structure is simple, the piezoelectric element 116 can be driven at the high repetition frequency without receiving the influence of the residual distortion. Hereinafter, the operation of the piezoelectric element drive circuit 200 will be described.

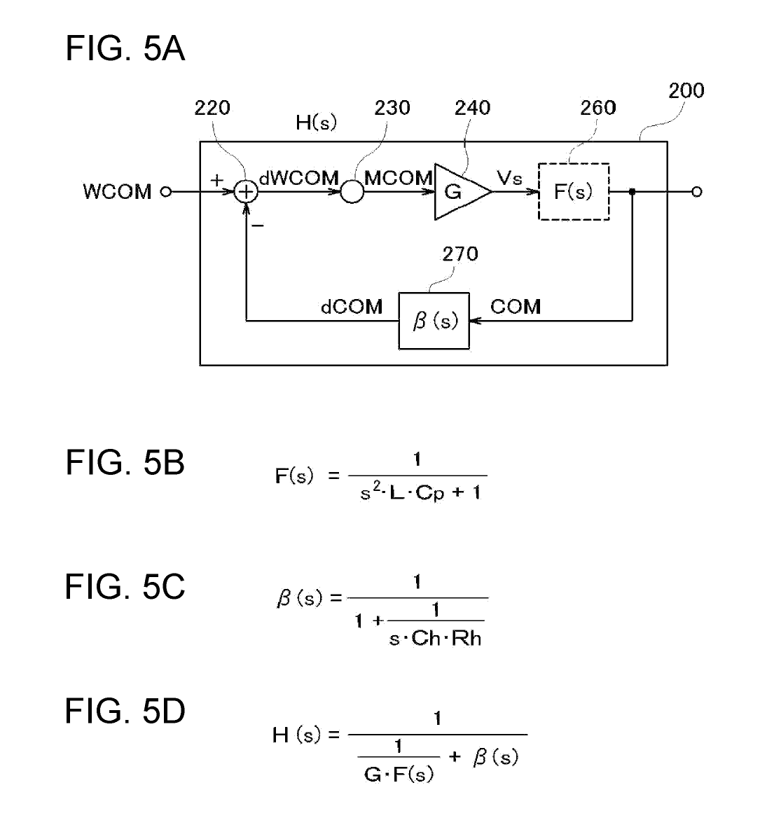

FIG. 5A is a block diagram for analysis of a frequency response characteristic of the piezoelectric element drive circuit 200 of the embodiment. First, the arithmetic circuit 220 subtracts dCOM (feedback signal) of the compensator 270 from WCOM (drive waveform signal) of the drive waveform signal generator 210, and generates dWCOM (error signal). After dWCOM is converted into MCOM (modulated signal) by the modulator 230, the signal is amplified by the digital power amplifier 240 and is converted into Vs (power amplified signal), and the signal is demodulated by the low pass filter 260 and is outputted as COM (drive signal). The outputted COM is subjected to the phase advance compensation by the compensator 270, and is negatively fed back as dCOM to WCOM, so that a feedback control system is constructed on the whole.

Here, when an inductance of the coil 250 is L, and the capacitance of the piezoelectric element 116 is Cp, a transfer function F(s) of the low pass filter 260 is given by an expression shown in FIG. 5B. A transfer function β(s) of the compensator 270 is given by an expression shown in FIG. 5C. Here, Ch represents the capacitance of the capacitor constituting the compensator 270, and Rh represents the resistance value of the resistor constituting the compensator 270. Accordingly, when a gain of the power amplification of the digital power amplifier 240 is G, a transfer function H(s) of the whole piezoelectric element drive circuit 200 is given by an expression shown in FIG. 5D.

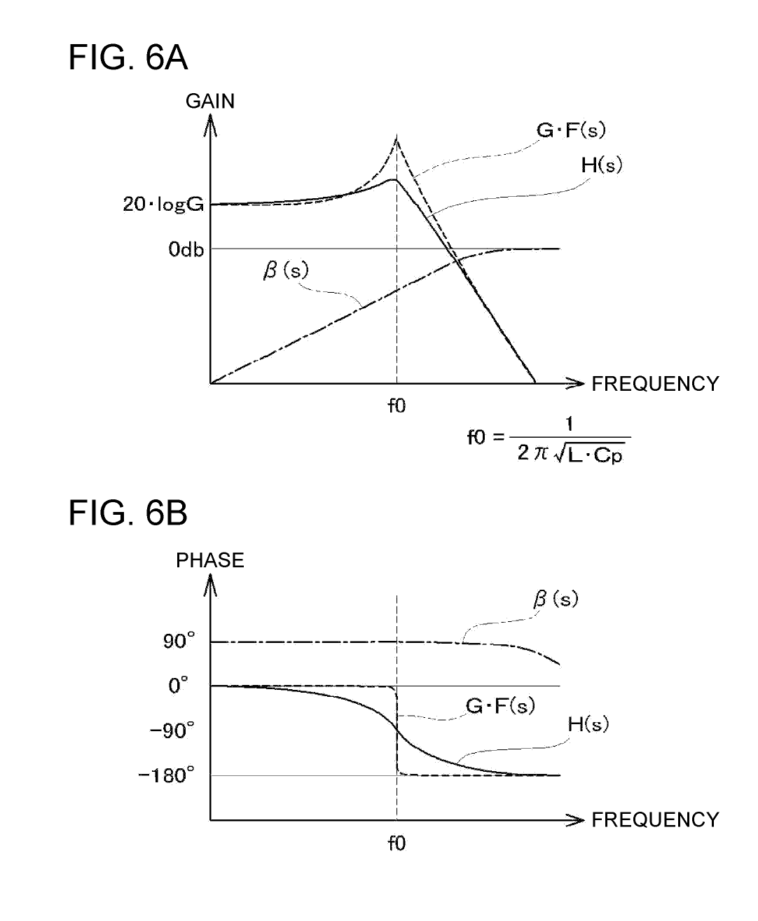

FIGS. 6A and 6B are board diagrams showing the frequency response characteristic of the transfer function H(s) of the whole piezoelectric element drive circuit 200. FIG. 6A is a gain diagram, and FIG. 6B is a phase diagram. Besides, the gain diagram and the phase diagram show a characteristic of a transfer function G•F(s) of the low pass filter 260 including the power amplifier 235 and a characteristic of the transfer function β(s) of the compensator 270 in addition to the characteristic of the transfer function H(s) of the whole piezoelectric element drive circuit 200.

As indicated by a broken line in the gain diagram of FIG. 6A, since the inductance of the coil 250, together with the capacitance of the piezoelectric element 116 (piezoelectric element), forms a resonant circuit, a sharp peak of the gain appears in the vicinity of a resonant frequency f0 determined by a calculation expression shown in the drawing. Then, COM is negatively fed back, so that the peak is suppressed. However, as shown in FIG. 6B, because of the phase characteristic of the low pass filter 260, the phase of COM is delayed by 180 degrees in a frequency area higher than the resonant frequency f0, if COM is negatively fed back as it is, there is a fear that the control unit 130 becomes unstable. Then, after the compensation to advance the phase is performed by using the phase advance compensator 270 having a characteristic indicated by an alternate long and short dash chain line in FIG. 6B, the signal is negatively fed back as dCOM (feedback signal). By doing so, COM can be negatively fed back without making the control unit 130 unstable, and consequently, the peak appearing on the gain diagram can be suppressed as indicated by a solid line in FIG. 6A.

Here, in the piezoelectric element drive circuit 200 of the embodiment, the peak of the gain is not completely suppressed, but a peak of +1 dB (about 1.25 times) or more remains. Thus, in a frequency area close to the resonant frequency f0, a gain larger than the gain G of the power amplifier 235 by at least +1 dB (about 1.25 times) or more can be obtained. In the piezoelectric element drive circuit 200 of the embodiment, this characteristic is used, and the residual distortion of the piezoelectric element 116 is eliminated.

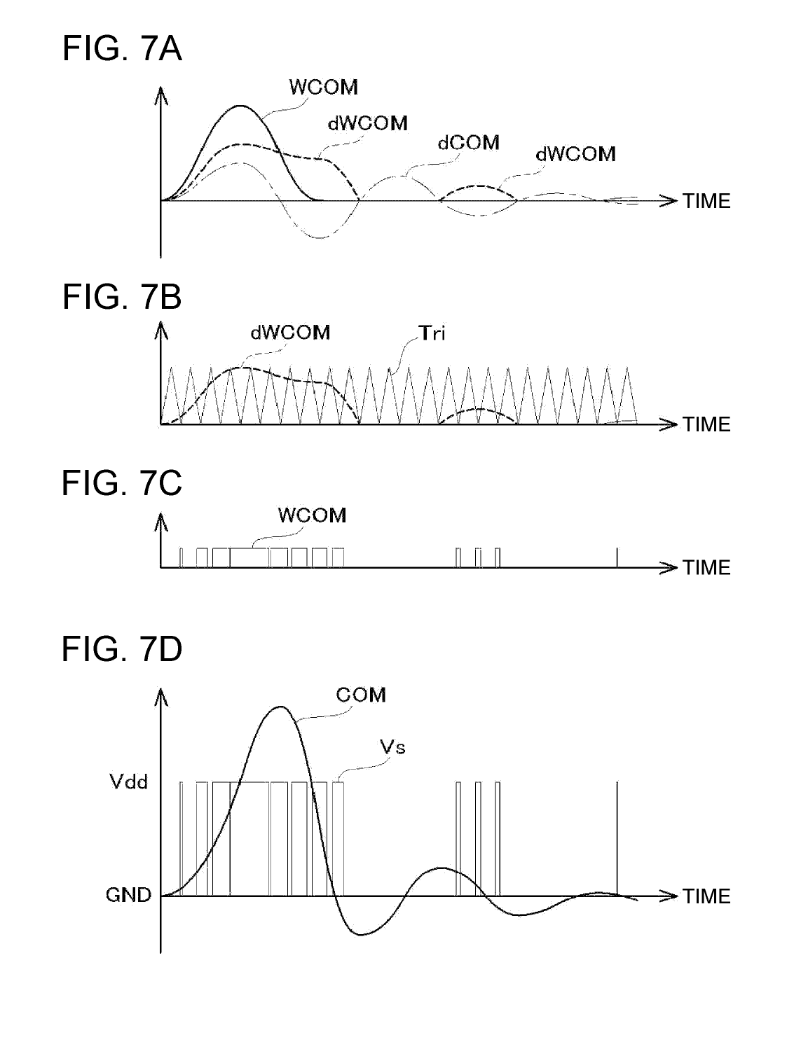

FIGS. 7A to 7D are explanatory views exemplifying the operation of the piezoelectric element drive circuit 200 of the embodiment. FIG. 7A shows a state where the arithmetic circuit 220 receives WCOM (drive waveform signal) from the drive waveform signal generator 210 and dCOM (feedback signal) from the compensator 270, and outputs dWCOM (error signal). The thus outputted dWCOM is inputted to the modulator 230, and is compared with Tri (triangular wave signal) having a specific period. FIG. 7B shows dWCOM and Tri compared in the modulator 230. The modulator 230 compares the two signals, generates MCOM (modulated signal) shown in FIG. 7C in which the high voltage state occurs when dWCOM is larger, and the low voltage state occurs when Tri is larger, and outputs the signal to the digital power amplifier 240. In the digital power amplifier 240, MCOM is power-amplified to Vs (power amplified signal) in which the voltage is changed between the voltage (power supply voltage Vdd) generated by the power supply of the digital power amplifier 240 and the ground voltage GND of the power supply, and Vs is outputted to the coil 250. Then, Vs inputted to the coil 250 is converted into COM (drive signal) in accordance with a gain characteristic shown in FIG. 6A, and COM is applied to the piezoelectric element 116.

Here, as described above with reference to FIG. 6A, the gain of the transfer function H(s) of the whole piezoelectric element drive circuit 200 increases in the vicinity of the resonant frequency f0 determined by the inductance L of the coil 250 and the capacitance Cp of the piezoelectric element 116. Thus, in COM, a slight overshoot and undershoot occur relative to a voltage range of Vs (from the ground voltage GND of the power supply to the power supply voltage Vdd). This becomes clear when a waveform of WCOM shown in FIG. 7A is compared with a waveform of COM shown in FIG. 7D. That is, as shown in FIG. 7A, WCOM increases from a voltage in the initial state and decreases again to the voltage in the initial state. On the other hand, COM increases from a voltage in the initial state and decreases to a voltage lower than the voltage in the initial state when the voltage decreases, and the undershoot occurs. Besides, although not clear from the comparison with WCOM, in COM, the overshoot occurs also when the signal increases from the voltage in the initial state. If the piezoelectric element 116 is driven by using such COM (especially, COM with the undershoot), the residual distortion generated in the piezoelectric element 116 is quickly eliminated, and COM can be applied at the high repetition frequency. Hereinafter, this point will be described in detail.

FIG. 8 is an explanatory view showing the electrostriction of the piezoelectric element 116 when COM with the undershoot is repeatedly applied to the piezoelectric element 116. A waveform indicated by a solid line in the drawing represents COM. As shown in the drawing, COM increases from the voltage Va in the initial state to the voltage Vb, and decreases to a lowest voltage V0 lower than the voltage Va, and then, quickly attenuates in a short time while oscillating around the voltage Va. Here, the reason why the oscillation of COM attenuates in a short time is that the piezoelectric element drive circuit 200 of the embodiment performs the phase advance compensation of COM and performs the negative feedback thereof. Besides, a waveform indicated by a broken line in the drawing represents the electrostriction of the piezoelectric element 116 generated correspondingly to such COM. Further, the horizontal axis of FIG. 8 indicates the passage of time.

When COM is increased from the voltage Va in the initial state to the voltage Vb during a period from a time point A to a time point B shown in the drawing, the electrostriction of the piezoelectric element 116 increases to La. Subsequently, when COM is decreased, the signal passes the voltage Va in the initial state and decreases to a voltage (lowest voltage V0) lower than the voltage Va by dV at a time point C shown in the drawing. As shown by a broken line in the drawing, the residual distortion is generated in the piezoelectric element 116 at the time point when COM returns to the voltage Va in the initial state. However, COM is further decreased from the state to the lowest voltage V0, so that the residual distortion is almost eliminated. Thereafter, the electrostriction of the piezoelectric element 116 slightly varies in accordance with residual oscillation generated in COM. However, the residual oscillation of COM attenuates in a short time, and when the voltage is stabilized to the voltage Va in the initial state, the electrostriction of the piezoelectric element 116 also returns to almost the initial state. After the electrostriction of the piezoelectric element 116 returns to almost the initial state in this way, COM is again applied to the piezoelectric element 116, so that the piezoelectric element 116 can be driven without being influenced by the residual distortion. Incidentally, it is sufficient if the lowest voltage V0 is a voltage lower than the voltage Va in the initial state, and the lowest voltage is not necessarily required to be a negative voltage. Here, the negative voltage means a voltage lower than the ground voltage of COM (that is, the ground voltage of the piezoelectric element 116). Particularly, in a so-called laminated element such as the piezoelectric element 116 of the embodiment, it is desirable that the lowest voltage VO does not become a large negative voltage in view of durability of the piezoelectric element 116.

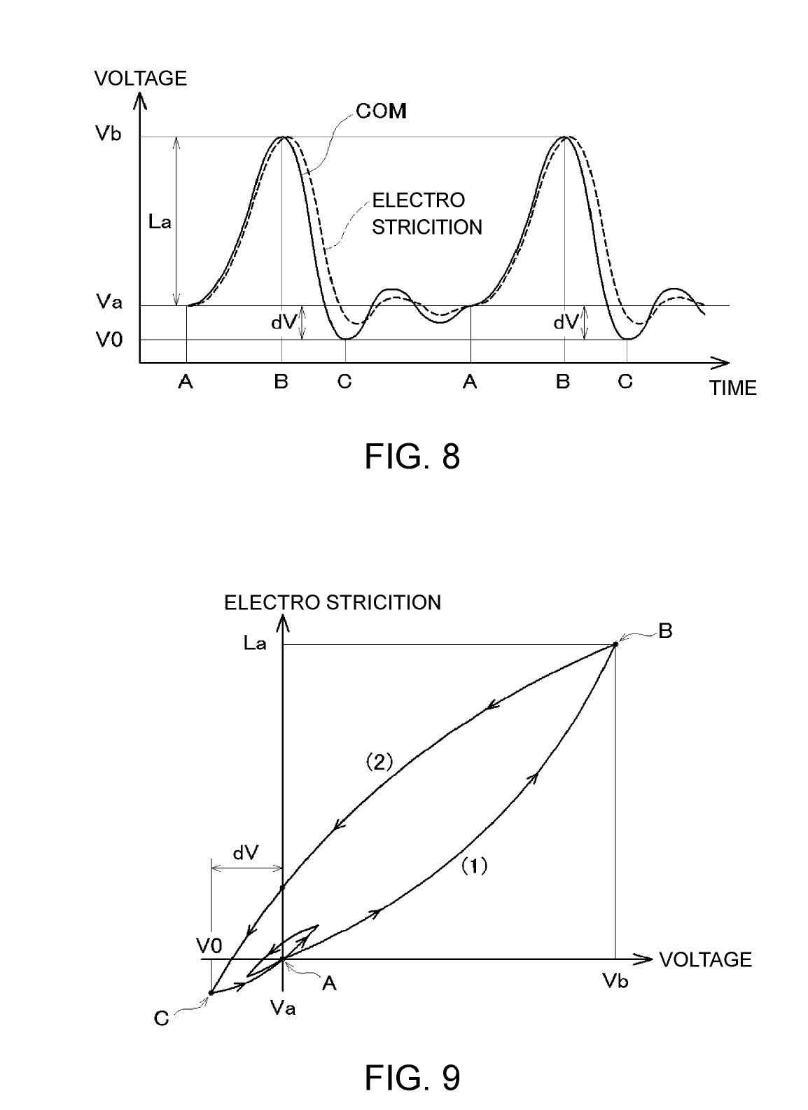

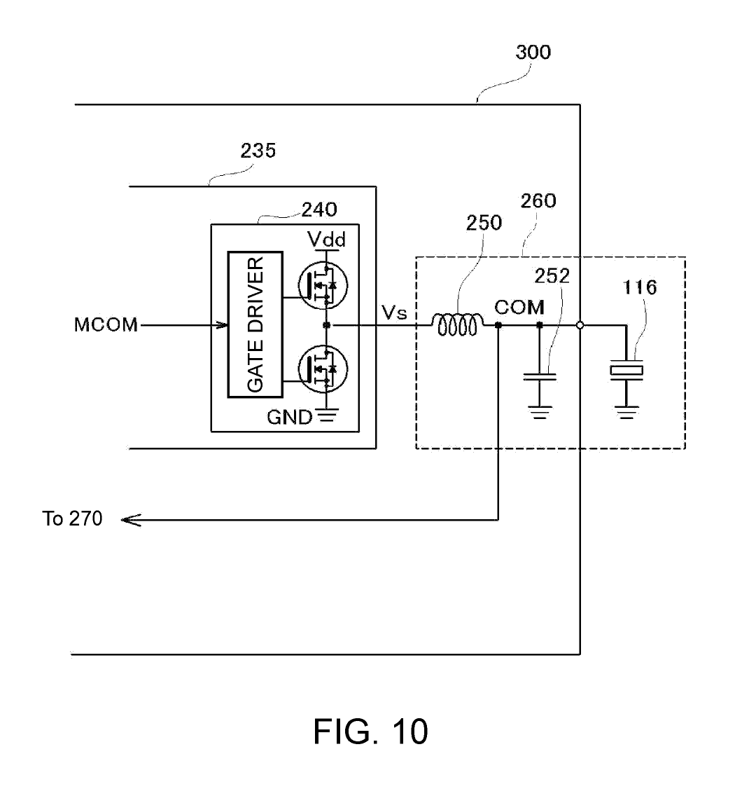

FIG. 9 is an explanatory view in which the behavior of the piezoelectric element 116 when COM is applied is shown on the plane specified by the voltage applied to the piezoelectric element 116 and the electrostriction of the piezoelectric element 116. A state indicated by “A” in FIG. 9 (state where the voltage Va in the initial state is applied to the piezoelectric element 116 and the electrostriction of the piezoelectric element 116 is 0) corresponds to the state at the time point A shown in FIG. 8. Besides, a state indicated by “B” in FIG. 9 (state where the voltage Vb is applied to the piezoelectric element 116 and the electrostriction of the piezoelectric element 116 is La) corresponds to the state at the time point B shown in FIG. 8. Further, a state indicated by “C” in FIG. 9 (state where the undershot voltage (lowest voltage V0) is applied to the piezoelectric element 116) corresponds to the state at the time point C shown in FIG. 8.

As shown in FIG. 9, when COM increases from the voltage Va in the initial state to the voltage Vb, the state of the piezoelectric element 116 changes from the state A to the state B through a path (1) shown in the drawing. Subsequently, when COM decreases, the state of the piezoelectric element 116 changes through a path (2) shown in the drawing. Thus, the electrostriction of the piezoelectric element 116 does not return to the initial state at the time point when COM decreases to the voltage Va, and the residual distortion is generated. However, since COM further decreases from the voltage Va, the state of the piezoelectric element 116 further moves along the path (2), and the residual distortion decreases in accordance with that. When COM decreases to the lowest voltage V0, the state of the piezoelectric element 116 reaches the state C, and the residual distortion is almost eliminated. Thereafter, although the state varies around the state A in accordance with the oscillation of COM around the voltage Va in the initial state, the variation is reduced in a short time and the state returns to the state A as the initial state. When COM is again applied in this state, the piezoelectric element 116 repeats the same operation as the foregoing operation.

As stated above, the piezoelectric element drive circuit 200 of the embodiment uses the undershooting COM and drives the piezoelectric element 116. Thus, the residual distortion generated in the piezoelectric element 116 can be reduced by the amount corresponding to the undershoot voltage (dV in the embodiment) of COM. Incidentally, in the piezoelectric element 116, the residual distortion of about ten to twenty percent of the amount of deformation generally occurs. Accordingly, in order to eliminate the residual distortion by the undershoot of COM, the undershoot voltage (dV in the embodiment) is desirably set to be about ten to twenty percent of the voltage (voltage from the voltage Va in the initial state to the voltage Vb) applied to the piezoelectric element 116.

If an attempt is made to eliminate the residual distortion of the piezoelectric element 116 by applying a voltage (here, the lowest voltage V0) lower than the voltage Va in the initial state without using the undershoot, a circuit to drive the piezoelectric element 116 is inevitably enlarged and complicated because of the following reason. First, COM is generated by causing Vs (power amplified signal) obtained by the digital power amplifier 240 to pass through the coil 250. The digital power amplifier 240 generates Vs by power-amplifying MCOM (modulated signal) from the modulator 230 to the signal in which the voltage is changed between the power supply voltage Vdd generated by the power supply and the ground voltage GND of the power supply. In this embodiment, the ground voltage GND is the voltage Va in the initial state of COM. If an attempt is made to generate a voltage lower than the voltage Va in the initial state, a power supply for generating the voltage lower than the ground voltage GND is additionally required. Although the additionally prepared power supply is not necessarily a negative voltage, in any event, plural power supplies are required. Therefore, the circuit to drive the piezoelectric element 116 is enlarged and complicated.

On the other hand, in the piezoelectric element drive circuit 200 of the embodiment, as described before with reference to FIGS. 6A and 6B, the characteristic of the compensator 27 has only to be set so that the peak of the gain in the vicinity of the resonant frequency f0 remains slightly. Besides, as is apparent from the description until now, the withstand voltage of the switch element (MOSFET) used in the power amplifier has only to be set according to the power supply voltage Vdd generated by the power supply and the ground voltage GND of the power supply, and the maximum amplitude of the generated COM is not necessarily required to be considered. In general, when the withstand voltage of the switch element (MOSFET) is reduced, the ON resistance can also be made low, and therefore, a further power saving effect can be expected. Thus, the power supply is not additionally required, and further, a large heat sink for heat dissipation is not required to be provided. Thus, the piezoelectric element drive circuit 200 is not enlarged and complicated.

Besides, in the piezoelectric element drive circuit 200 of the embodiment, since the phase advance compensation of COM is performed and the negative feedback is performed, even if COM is undershot, the residual oscillation after that attenuates in a short time. Thus, after the application of COM, the piezoelectric element 116 returns to the initial state (state before the application of COM) in a short time. Accordingly, even when COM is applied at the high repetition frequency, the piezoelectric element 116 can be driven without being influenced by the residual distortion.

### D. Modified Example

In the embodiment or modified example described above, the description is made on the assumption that the low pass filter 260 is constructed of the coil 250 and the piezoelectric element 116. However, a capacitor is provided to be connected in parallel to the piezoelectric element 116, and the low pass filter 260 may be constructed of this capacitor, the coil 250 and the piezoelectric element 116.

FIG. 10 is an explanatory view exemplifying a part of a piezoelectric element drive circuit 300 of the modified example including the foregoing structure. As shown in the drawing, in the piezoelectric element drive circuit 300 of the modified example, a capacitor 252 (capacitive element) is provided to be connected in parallel to a piezoelectric element 116. In the structure as stated above, a resonant circuit includes an inductance L of a coil 250, a capacitance Cp of the piezoelectric element 116, and a capacitance Cc of the capacitor 252. Since the capacitance Cp of the piezoelectric element 116 and the capacitance Cc of the capacitor 252 connected in parallel to each other can be treated as a synthetic capacitance (the magnitude is Cp+Cc), a resonant frequency of the resonant circuit is a frequency determined by the inductance L of the coil 250 and the synthetic capacitance Cp+Cc.

The capacitance Cp of the piezoelectric element 116 as a drive load of the piezoelectric element drive circuit 300 is roughly determined within a range corresponding to a desired piezoelectric performance. Accordingly, if the capacitor 252 does not exist, in order to set the resonant frequency to a desired frequency, the inductance L of the coil 250 is required to be adjusted. As a result, if a large inductance L is required, a large coil 250 is required, and the piezoelectric element drive circuit 300 becomes large. However, also in this case, if the capacitor 252 is connected in parallel to the piezoelectric element 116, the capacitance of the capacitor 252 is suitably set, so that the resonant frequency can be set to the desired frequency without enlarging the coil 250.

Although the piezoelectric element drive circuit of the embodiment is described, the invention is not limited to the embodiment and the modified example described above, but can be carried out in various modes within the scope not departing from the gist thereof

For example, in the foregoing embodiment or the modified example, the system called the so-called pulse width modulation (PWM) is used as the pulse modulation system. However, the pulse modulation system is not limited to the PWM, and another pulse modulation system, for example, a system called pulse density modulation (PDM) may be used. Especially, if a ΔΣ modulation system to integrate a difference between COM (drive waveform signal) and Vs (power amplified signal) is used, a variation in the power supply voltage can also be handled.

Besides, the piezoelectric element drive circuit 200 can be applied to various electronic equipments including a medical equipment, such as a liquid ejecting apparatus used to form a micro-capsule containing a medicine or a nutritional supplement. Especially, in the medical equipment, since the safety and the uniformity of the amount of the medicine or the nutritional supplement are required, the needs for the medical equipment can be satisfied by applying the piezoelectric element drive circuit 200, 300 of the invention in which the ejection amount is stable.

Besides, the piezoelectric element drive circuit can be applied also to a diagram type liquid feeding pump used in a liquid circulating apparatus to cool a heat source generated in a projector or the like by circulating a liquid such as a refrigerant liquid. If the piezoelectric element drive circuit 200, 300 of the embodiment of the invention is applied to the liquid circulating apparatus, as stated above, the liquid circulating apparatus which realizes a stable ejection amount and has a high efficiency and a small size can be provided.

This application claims priority to Japanese Patent Application No. 2011-148900, filed on Jul. 5, 2011, the entirety of which is hereby incorporated by reference.

What is claimed is:

1. A piezoelectric element drive circuit for driving a piezoelectric element by applying a specified drive signal to the piezoelectric element, comprising:
a drive waveform signal output circuit to output a drive waveform signal as a reference of the drive signal;
an arithmetic circuit to generate an error signal by taking a difference between the drive waveform signal and a feedback signal generated using the drive signal applied to the piezoelectric element;
a power amplifier that receives power from a power supply and power-amplifies the error signal to generate a power amplified signal whose voltage changes between a power supply voltage generated by the power supply and a ground voltage of the power supply;
an inductive element that connects the power amplifier to the piezoelectric element and supplies the power amplified signal from the power amplifier as the drive signal to the piezoelectric element; and
a compensator that feeds back negatively a signal, which is obtained by performing a phase advance compensation, as a compensation to advance a phase, of the drive signal from the inductive element, as the feedback signal to the arithmetic circuit, wherein the compensator is a circuit in which a lowest voltage of the drive signal applied to the piezoelectric element becomes lower than the ground voltage of the power supply.

2. The piezoelectric element drive circuit according to claim 1, wherein the compensator is the circuit in which a voltage difference between the lowest voltage of the drive signal applied to the piezoelectric element and the ground voltage is a value of ten to twenty percent of a voltage difference between a highest voltage of the drive signal and the ground voltage.

3. The piezoelectric element drive circuit according to claim 1, further comprising a capacitive element connected in parallel to the piezoelectric element.

4. The piezoelectric element drive circuit according to claim 1, wherein the power amplifier includes:
a modulator to generate a modulated signal by pulse-modulating the error signal; and
a digital power amplifier that receives the power from the power supply and generates the power-amplified signal by digitally power-amplifying the modulated signal.

5. A liquid ejecting apparatus comprising:
the piezoelectric element drive circuit according to claim 1; and
a pulsation generating part including a liquid chamber into which liquid flows, a piezoelectric element to deform the liquid chamber, and an ejection nozzle to eject the liquid flowing into the liquid chamber, wherein
the drive signal outputted from the piezoelectric element drive circuit is applied to the piezoelectric element, and the liquid flowing into the liquid chamber is ejected from the ejection nozzle.

6. A liquid ejecting apparatus comprising:
the piezoelectric element drive circuit according to claim 2; and
a pulsation generating part including a liquid chamber into which liquid flows, a piezoelectric element to deform the liquid chamber, and an ejection nozzle to eject the liquid flowing into the liquid chamber, wherein
the drive signal outputted from the piezoelectric element drive circuit is applied to the piezoelectric element, and the liquid flowing into the liquid chamber is ejected from the ejection nozzle.

7. A liquid ejecting apparatus comprising:
the piezoelectric element drive circuit according to claim 3; and
a pulsation generating part including a liquid chamber into which liquid flows, a piezoelectric element to deform the liquid chamber, and an ejection nozzle to eject the liquid flowing into the liquid chamber, wherein
the drive signal outputted from the piezoelectric element drive circuit is applied to the piezoelectric element, and the liquid flowing into the liquid chamber is ejected from the ejection nozzle.

8. A liquid ejecting apparatus comprising:
the piezoelectric element drive circuit according to claim 4; and
a pulsation generating part including a liquid chamber into which liquid flows, a piezoelectric element to deform the liquid chamber, and an ejection nozzle to eject the liquid flowing into the liquid chamber, wherein
the drive signal outputted from the piezoelectric element drive circuit is applied to the piezoelectric element, and the liquid flowing into the liquid chamber is ejected from the ejection nozzle.

9. A medical equipment comprising the piezoelectric element drive circuit according to claim 1.
